(19) United States
(12) Patent Application Publication
(10) Pub. No.: US 2019/0152195 A1
(43) Pub. Date: May 23, 2019

(54) THERMOPLASTIC ELASTOMER LAMINATE AND ORGANIC ELECTROLUMINESCENCE DEVICE

(71) Applicant: ZEON CORPORATION, Chiyoda-ku, Tokyo (JP)

(72) Inventor: Hiroyasu INOUE, Tokyo (JP)

(73) Assignee: ZEON CORPORATION, Chiyoda-ku, Tokyo (JP)

(21) Appl. No.: 16/316,804

(22) PCT Filed: Jul. 12, 2017
(86) PCT No.: PCT/JP2017/025453

§ 371 Date: Jan. 10, 2019

(30) Foreign Application Priority Data
Jul. 28, 2016 (JP) 2016-148237

(51) Int. Cl. B32B 25/02; C09J 109/06; C09J 11/04; C09J 11/06; C09J 201/00; H01L 51/50; H05B 33/04

(52) U.S. Cl. CPC B32B 25/02; C09J 109/06; C09J 11/04; C09J 11/06; B32B 25/18; H01L 51/5012; H05B 33/04; H01L 51/5056; H01L 51/5072; C09J 201/00

(57) ABSTRACT

A thermoplastic elastomer layered body including a first resin layer, a moisture absorption layer, and a second resin layer in this order, wherein the first resin layer is formed of a first thermoplastic elastomer, the moisture absorption layer contains particles that have hygroscopicity and are dispersed in the moisture absorption layer, and the second resin layer is formed of a second thermoplastic elastomer; and an organic electroluminescent device including the same. Each layer may contain a hydrogenated styrene-isoprene copolymer or a silane modified product thereof as a main component.

### FIELD

The present invention relates to a thermoplastic elastomer layered body and an organic electroluminescent device that includes the thermoplastic elastomer layered body.

### BACKGROUND

An organic electroluminescent device (hereinafter, which may be referred to as an “organic EL device” as appropriate) generally includes a substrate plate such as a glass plate, and an electrode and a light-emitting layer disposed thereon. The organic EL device may further include a gas barrier layer and an adhesive layer for bonding such a layer in order to prevent the penetration of water into the light-emitting layer. Further, it has been proposed that the penetration of water is further prevented by using a material containing a moisture absorbent as a part of layer constituting such an adhesive layer (Patent literature 1).

### CITATION LIST

### Patent Literature

Patent Literature 1: Japanese Translation of PCT Patent Application Publication No. 2015-504457 A

### SUMMARY

### Technical Problem

However, when the adhesive layer containing the moisture absorbent is used for bonding the gas barrier layer, the adhesive layer sometimes causes an adverse effect on the light-emitting layer and rather accelerates the deterioration of the light-emitting layer. Thus, when the adhesive layer containing the moisture absorbent is used, problems such as generation of a large dark spot may be caused after using the organic EL device for a long period of time.

Thus, an object of the present invention is to provide a material usable for bonding a layer constituting an organic EL device, which causes a reduced degree of an adverse effect on a light-emitting layer, is capable of effectively preventing the penetration of water into the light-emitting layer, and is capable of reducing problems such as generation of a large dark spot.

Another object of the present invention is to provide an organic EL device in which problems such as generation of a large dark spot is reduced.

### Solution to Problem

The present inventor carried out studies to solve the aforementioned problems. As a result, the present inventor has found that a dispersant that is used together with a moisture absorbent in an adhesive layer causes an adverse effect on a light-emitting layer. Specifically, according to the findings by the present inventor, the dispersant which resides at the interface between the adhesive layer and the light-emitting layer or reaches the light-emitting layer after bleeding from the adhesive layer may, for example, cause an adverse effect on the light-emitting layer by chemically reacting with the light-emitting layer or inhibit adhesion of each layer constituting an organic EL device. On the other hand, the moisture absorbent is often formed in a particle shape and such particles are sometimes aggregated into secondary particles having a diameter larger than a primary particle diameter. Thus, when a ratio of the dispersant is decreased, the flatness of the adhesive layer may deteriorate by such secondary particles of the moisture absorbent, thereby causing a physical adverse effect on the light-emitting layer.

As a result of further studies on such phenomena, the present inventor has arrived at an idea of adopting as a material of the adhesive layer a thermoplastic elastomer, i.e., a material that exhibits characteristics of rubber at a normal temperature and is plasticized at a high temperature to allow molding processing. As a result of further studies, the present inventor has found that, when such an thermoplastic elastomer is adopted as an outer layer of the adhesive layer and a layer that contains particles having hygroscopicity is adopted as an inner layer of the adhesive layer, it becomes possible to prevent the bleeding of the dispersant and the chemical reaction between the dispersant and the light-emitting layer in a bonding process and also becomes possible to effectively prevent an undesired phenomenon such as a physical adverse effect on the light-emitting layer caused by the secondary particle of the moisture absorbent, which consequently makes it possible to prevent problems such as generation of a large dark spot after using the organic EL device for a long period of time, thereby completing the present invention.

That is, the present invention is as follows.

(1) A thermoplastic elastomer layered body comprising a first resin layer, a moisture absorption layer, and a second resin layer in this order, wherein

the first resin layer is formed of a first thermoplastic elastomer,

the moisture absorption layer contains particles that have hygroscopicity and are dispersed in the moisture absorption layer, and

the second resin layer is formed of a second thermoplastic elastomer.

(2) The thermoplastic elastomer layered body according to (1), wherein the first thermoplastic elastomer and the second thermoplastic elastomer contain a hydrogenated styrene-isoprene copolymer or a silane modified product thereof as a main component.

(3) The thermoplastic elastomer layered body according to (1), wherein the first thermoplastic elastomer and the second thermoplastic elastomer contain a silane modified product of a hydrogenated styrene-isoprene copolymer as a main component.

(4) The thermoplastic elastomer layered body according to any one of (1) to (3), wherein the moisture absorption layer contains a styrene-isoprene copolymer or a silane modified product thereof as a main component.

(5) The thermoplastic elastomer layered body according to any one of (1) to (4), wherein the moisture absorption layer contains a dispersant.

(6) The thermoplastic elastomer layered body according to any one of (1) to (5), wherein both the first resin layer and the second resin layer do not substantially contain a dispersant.

(7) An organic electroluminescent device comprising the thermoplastic elastomer layered body according to any one of (1) to (6).

### Advantageous Effects of Invention

The thermoplastic elastomer layered body of the present invention can be used as an adhesive layer in bonding of layers constituting an organic EL device, and such use can effectively prevent the penetration of water into a light-emitting layer without large adverse effects on the light-emitting layer, whereby problems such as generation of a large dark spot in the organic EL device can be reduced.

The organic EL device of the present invention can be a device in which problems such as generation of a large dark spot in the organic EL device can be reduced.

### BRIEF DESCRIPTION OF DRAWINGS

FIG. 1 is a cross-sectional view schematically illustrating an example of a thermoplastic elastomer layered body of the present invention.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

[1. Summary of Thermoplastic Elastomer Layered Body]

The thermoplastic elastomer layered body of the present invention includes a first resin layer, a moisture absorption layer, and a second resin layer in this order. The first resin layer is formed of a first thermoplastic elastomer, and the second resin layer is formed of a second thermoplastic elastomer. That is, the first resin layer may be formed by molding the first thermoplastic elastomer into a layer shape. The second resin layer may be formed by molding the second thermoplastic elastomer into a layer shape. The moisture absorption layer contains particles dispersed therein that have hygroscopicity (hereinafter the particles may simply be referred to as “moisture absorption particles”). The thermoplastic elastomers constituting the first thermoplastic elastomer and the second thermoplastic elastomer may be the same material or different materials.

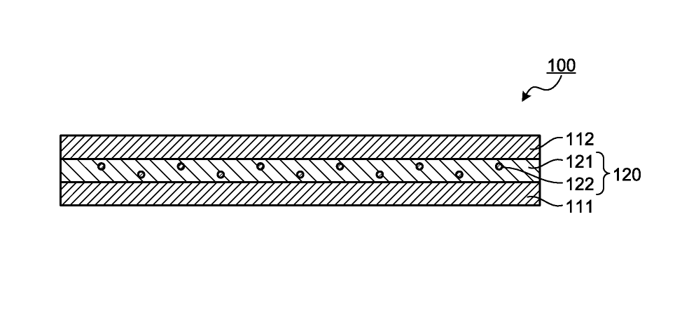

FIG. 1 is a cross-sectional view schematically showing an example of a thermoplastic elastomer layered body of the present invention. In FIG. 1, the thermoplastic elastomer layered body 100 includes a first resin layer 111, a moisture absorption layer 120, and a second resin layer 112 in this order. The moisture absorption layer 120 contains a resin 121 and particles 122 dispersed therein that have hygroscopicity.

[2. Thermoplastic Elastomer]

In the present application, the thermoplastic elastomer refers to a material that exhibits characteristics of rubber at a normal temperature and is plasticized at high temperature to allow molding processing. Such thermoplastic elastomers have a characteristic that is less prone to cause elongation or fracture with small loads. Specifically, the thermoplastic elastomer exhibits a Young's modulus of 0.001 to 1 GPa and a tensile elongation (fracture elongation) of a value of 100 to 1000% at 23° C. The storage elastic modulus of the thermoplastic elastomer drops sharply in a high temperature range of 40° C. or higher and 200° C. or lower, so that the loss tangent tanδ (loss elastic modulus/storage elastic modulus) has a peak or shows a value exceeding 1, and the thermoplastic elastomer softens. Young's modulus and tensile elongation may be measured in accordance with JIS K7113. The loss tangent tanδ may be measured by a commercially available dynamic viscoelasticity measuring apparatus.

Thermoplastic elastomers generally contain little or no residual solvent, and therefore emit less gases. Therefore, since the thermoplastic elastomer is less prone to generate gases in a low-pressure environment, it is possible to prevent the resin layer itself from becoming a gas generation source. In addition, unlike a thermosetting resin or a photocurable resin, the process can be simplified because it does not require a treatment for crosslinking in the middle of the process.

[2.1. Main Component of Thermoplastic Elastomer]

As the thermoplastic elastomer, those containing a polymer of a variety of types as main components may be used. Examples of the polymers contained in the thermoplastic elastomer may include an ethylene-α-olefin copolymer such as an ethylene-propylene copolymer; an ethylene-α-olefin-polyene copolymer; a copolymer of ethylene and an unsaturated carboxylic acid ester such as ethylene-methyl methacrylate and ethylene-butyl acrylate; a copolymer of ethylene and a fatty acid vinyl ester such as ethylene-vinyl acetate; a polymer of an acrylic acid alkyl ester such as ethyl acrylate, butyl acrylate, hexyl acrylate, 2-ethylhexyl acrylate, and lauryl acrylate; a diene-based copolymer such as polybutadiene, polyisoprene, a styrene-butadiene random copolymer, a styrene-isoprene random copolymer, an acrylonitrile-butadiene copolymer, a butadiene-isoprene copolymer, a butadiene-(meth)acrylic acid alkyl ester copolymer, a butadiene-(meth)acrylic acid alkyl ester-acrylonitrile copolymer, and a butadiene-(meth)acrylic acid alkyl ester-acrylonitrile-styrene copolymer; an aromatic vinyl-conjugated diene-based block copolymer such as a butylene-isoprene copolymer, a styrene-butadiene block copolymer, a hydrogenated styrene-butadiene block copolymer, a styrene-isoprene block copolymer, and a hydrogenated styrene-isoprene block copolymer; and a low crystallizable polybutadiene, a styrene graft ethylene-propylene elastomer, a thermoplastic polyester elastomer, and an ethylene-based ionomer.

The polymer contained in the thermoplastic elastomer is preferably a hydrogenated product of an aromatic vinyl compound-conjugated diene block copolymer such as a hydrogenated styrene-butadiene block copolymer and a hydrogenated styrene-isoprene block copolymer. Specific examples thereof may include those described in prior art literatures such as Japanese Patent Application Laid-Open Nos. Hei. 2-133406 A, Hei. 2-305814 A, Hei. 3-72512 A, and Hei. 3-74409 A, and International Publication No. WO2015/099079.

Examples of the particularly preferable form of the block of the hydrogenated product of the aromatic vinyl compound-conjugated diene block copolymer may include: a triblock copolymer in which blocks [A] of a hydrogenated product of an aromatic vinyl polymer are bonded to both ends of a block [B] of a hydrogenated product of a conjugated diene polymer; and a pentablock copolymer in which the polymer blocks [B] are bonded to both ends of the polymer block [A], and the polymer blocks [A] are bonded to respective other ends of both the polymer blocks [B]. In particular, the triblock copolymer of [A]-[B]-[A] is particularly preferable because it is easily produced and the properties thereof as a thermoplastic elastomer can be set within desired ranges.

In the hydrogenated product of the aromatic vinyl compound-conjugated diene block copolymer, a ratio (wA/wB) of a weight fraction wA of all the polymer blocks [A] in the entire block copolymer relative to a weight fraction wB of all the polymer blocks [B] in the entire block copolymer is usually 20/80 or more, and preferably 30/70 or more, and is usually 60/40 or less, and preferably 55/45 or less. When the aforementioned ratio wA/wB is equal to or more than the lower limit value of the aforementioned range, heat resistance of the thermoplastic elastomer can be improved. When the ratio is equal to or less than the upper limit value thereof, flexibility of the thermoplastic elastomer can be enhanced, so that a barrier property of the thermoplastic elastomer can be stabilized and favorably maintained. Further, since the sealing temperature can be lowered by lowering the glass transition temperature of the block copolymer, it is possible to suppress thermal degradation of elements such as an organic EL element and an organic semiconductor element.

The hydrogenated product of the aromatic vinyl compound-conjugated diene block copolymer is a product obtained by hydrogenating carbon-carbon unsaturated bonds in a main chain and a side chain and carbon-carbon of the aromatic ring of an aromatic vinyl compound-conjugated diene block copolymer such as a styrene-butadiene block copolymer and a styrene-isoprene block copolymer. The hydrogenation rate is usually 90% or more, preferably 97% or more, and more preferably 99% or more. The higher the hydrogenation rate, the better the heat resistance and light resistance of the thermoplastic elastomer can be made. Herein, the hydrogenation rate of the hydrogenated product may be determined by the measurement by ¹H-NMR.

The hydrogenation rate of carbon-carbon unsaturated bonds in the main chain and the side chain of the aforementioned block copolymer is preferably 95% or more, and more preferably 99% or more. By increasing the hydrogenation rate of the carbon-carbon unsaturated bonds in the main chain and the side chain of the aforementioned block copolymer, light resistance and oxidation resistance of the thermoplastic elastomer can be further enhanced.

The hydrogenation rate of the carbon-carbon unsaturated bond of the aromatic ring of the aforementioned block copolymer is preferably 90% or more, more preferably 93% or more, and particularly preferably 95% or more. By increasing the hydrogenation rate of the carbon-carbon unsaturated bond of the aromatic ring, the glass transition temperature of the hydrogenated product is increased, so that heat resistance of the thermoplastic elastomer can be effectively increased. In addition, the photoelastic coefficient of the thermoplastic elastomer can be lowered to suppress the expression of retardation during bonding.

The weight-average molecular weight (Mw) of the polymer contained in the thermoplastic elastomer as a main component is usually 30,000 or more, preferably 40,000 or more, and still more preferably 45,000 or more, and is usually 200,000 or less, preferably 150,000 or less, and still more preferably 100,000 or less. The weight-average molecular weight of the polymer may be measured as a polystyrene-equivalent value by gel permeation chromatography using tetrahydrofuran as a solvent. The molecular weight distribution (Mw/Mn) of the polymer is preferably 3 or less, more preferably 2 or less, and particularly preferably 1.5 or less, and is preferably 1.0 or more. When the weight-average molecular weight Mw and the molecular weight distribution Mw/Mn of the polymer fall within the aforementioned ranges, mechanical strength and heat resistance of the thermoplastic elastomer can be improved.

Further examples of the polymers contained in the thermoplastic elastomer may include a polymer having an alkoxysilyl group in its molecular structure. Such a polymer may be obtained by introducing an alkoxysilyl group into the various polymers exemplified above. The introduction of such an alkoxysilyl group is also referred to as silane modification. In the silane modification, an alkoxysilyl group may be directly bonded to the polymer, or may be bonded via a divalent organic group such as an alkylene group, for example.

The polymer having an alkoxysilyl group is particularly excellent in adhesiveness to materials such as glass, an inorganic substance, or a metal, for example. Therefore, when the element of the organic EL device is sealed by the thermoplastic elastomer layered body of the present invention, the adhesiveness between the thermoplastic elastomer layered body and the element can be particularly increased. Thus, the thermoplastic elastomer layered body can maintain sufficient adhesion even after exposure to a high-temperature and high-humidity environment for a long period of time, which is commonly used in reliability evaluation of organic EL devices.

The introduction amount of the alkoxysilyl group is usually 0.1 part by weight or more, preferably 0.2 part by weight or more, and still more preferably 0.3 part by weight or more, and is usually 10 parts by weight or less, preferably 5 parts by weight or less, and still more preferably 3 parts by weight or less, relative to 100 parts by weight of the polymer before the introduction of the alkoxysilyl group. When the introduction amount of the alkoxysilyl group falls within the aforementioned range, a degree of cross-linking between the alkoxysilyl groups decomposed by water or the like can be prevented from becoming excessively high, so that high adhesiveness can be maintained. Examples of materials having an alkoxysilyl group used for silane modification and methods of modification may include those described in prior art literatures such as International Publication No. WO2015/099079.

[2.2. Optional Component of Thermoplastic Elastomer: Moisture Absorption Particles and Dispersant]

In the thermoplastic elastomer layered body of the present invention, the moisture absorption layer contains moisture absorption particles and may contain a dispersant whereas it is preferable that the first thermoplastic elastomer constituting the first resin layer and the second thermoplastic elastomer constituting the second resin layer do not contain moisture absorption particles and a dispersant at all or substantially do not contain moisture absorption particles and a dispersant. That they substantially do not contain moisture absorption particles means that the content ratio of moisture absorption particles in each of the first thermoplastic elastomer and the second thermoplastic elastomer is preferably 2% by weight or less, more preferably 0.5% by weight or less, and ideally 0% by weight. That they substantially do not contain a dispersant means that the content ratio of the dispersant in each of the first thermoplastic elastomer and the second thermoplastic elastomer is preferably 1.5% by weight or less, more preferably 0.5% by weight or less, and ideally 0% by weight. By adopting such a thermoplastic elastomer, when the thermoplastic elastomer layered body of the present invention is used as an adhesive layer for bonding components of an organic EL device, undesirable phenomena such as adverse effects on a light-emitting layer can be effectively prevented.

[2.3. Optional Component of Thermoplastic Elastomer: Others]

The first thermoplastic elastomer constituting the first resin layer and the second thermoplastic elastomer constituting the second resin layer may contain optional components in addition to the polymers described above. Examples of the optional components may include a plasticizer for adjusting glass transition temperature and elastic modulus, a light stabilizer for improving weather resistance and heat resistance, an ultraviolet absorber, an antioxidant, a lubricant, and an inorganic filler. As the optional components, one type thereof may be solely used, and two or more types thereof may also be used in combination at any ratio.

Examples of the antioxidant may include a phosphorus-based antioxidant, a phenol-based antioxidant, and a sulfur-based antioxidant, and a phosphorus-based antioxidant having low tendency to cause coloration is preferable.

Examples of the phosphorus-based antioxidant may include a monophosphite-based compound such as triphenylphosphite, diphenylisodecylphosphite, phenyldiisodecylphosphite, tris(nonylphenyl)phosphite, tris(dinonylphenyl)phosphite, tris(2,4-di-t-butylphenyl)phosphite, and 10-(3,5-di-t-butyl-4-hydroxybenzyl)-9,10-dihydro-9-oxa-10-phosphaphenanthrene-10-oxide; a diphosphite-based compound such as 4,4′-butylidene-bis(3-methyl-6-t-butylphenyl-di-tridecylphosphite), 4,4′-isopropylidene-bis(phenyl-di-alkyl(C12 to C15)phosphite); and compounds such as 6-[3-(3-t-butyl-4-hydroxy-5-methylphenyl)propoxy]-2,4,8,10-tetrakis-t-butyldibenzo[d,f][1.3.2]dioxaphosphepine, and 6-[3-(3,5-di-t-butyl-4-hydroxyphenyl)propoxy]-2,4,8,10-tetrakis-t-butyldibenzo[d,f][1.3.2]dioxaphosphepin.

Examples of the phenol-based antioxidant may include compounds such as pentaerythrityl·tetrakis[3-(3,5-di-t-butyl-4-hydroxyphenyl)propionate], 2,2-thio-diethylene bis[3-(3,5-di-t-butyl-4-hydroxyphenyl)propionate], octadecyl-3-(3,5-di-t-butyl-4-hydroxyphenyl)propionate, 3,9-bis{2-[3-(3-t-butyl-4-hydroxy-5-methylphenyl)propionyloxy]-1,1-dimethylethyl}-2,4,8,10-tetraoxaspiro[5,5]undecane, and 1,3,5-trimethyl-2,4,6-tris(3,5-di-butyl-4-hydroxybenzyl)benzene.

Examples of the sulfur-based antioxidant may include compounds such as dilauryl-3,3′-thiodipropionate, dimyristyl-3,3′-thiodipropionate, distearyl-3,3′-thiodipropionate, laurylstearyl-3,3′-thiodipropionate, pentaerythritol-tetrakis-(β-lauryl-thio-propionate), and 3,9-bis(2-dodecylthioethyl)-2,4,8,10-tetraoxaspiro[5,5]undecane.

The amount of the antioxidant is usually 0.01 part by weight or more, preferably 0.05 part by weight or more, and still more preferably 0.1 part by weight or more, and is usually 1 part by weight or less, preferably 0.5 part by weight or less, and still more preferably 0.3 part by weight or less, relative to 100 parts by weight of the polymer as the main component. When the antioxidant is used in an amount of the lower limit value or more of the aforementioned range, durability of the first resin layer and the second resin layer can be improved. Excessive amount of the antioxidant used beyond the upper limit provides almost no further improvement.

When the thermoplastic elastomer contains the polymer as the main component and optional components, the thermoplastic elastomer may be prepared by mixing them.

Examples of the method for mixing the polymer as the main component and the optional components may include a method of dissolving the optional components in an appropriate solvent and mixing it with the solution of the polymer, and then removing the solvent to collect the thermoplastic elastomer containing the optional components; and a method of kneading the polymer in a molten state with the optional components in a kneader such as a twin-screw kneader, a roll, a brabender, or an extruder.

[3. Moisture Absorption Layer Material]

The material constituting the moisture absorption layer constituting the thermoplastic elastomer layered body of the present invention (hereinafter, this material may be referred to as a “moisture absorption layer material”) is not particularly limited as long as the material contains the moisture absorption particles. The moisture absorption layer material preferably contains the thermoplastic elastomer and the moisture absorption particles. More preferably, the moisture absorption layer material contains the thermoplastic elastomer, the moisture absorption particles, and the dispersant.

[3.1. Moisture Absorption Particle]

The moisture absorption particle is a particle that has a weight change ratio within a specific range obtained after being allowed to stand at 20° C. and 90% RH for 24 hours. The specific range of the weight change ratio is usually 3% or more, preferably 10% or more, and more preferably 15% or more. No particular limitation is imposed on the upper limit of the weight change ratio, however, it is preferably 100% or less. By using the moisture absorption particles having such high hygroscopicity, water is sufficiently absorbed with a small amount of the moisture absorption particles without inhibiting characteristics of rubber originally possessed by the thermoplastic elastomer, thus it is advantageous.

The weight change ratio described above may be calculated by the following formula (A1). In the following formula (A1), W1 represents a weight of the particles before being allowed to stand in an environment of 20° C. and 90% Rh, and W2 represents a weight of the particles after being allowed to stand in the environment of 20° C. and 90% Rh for 24 hours.

Weight change ratio (%)=(W2−W1)/W1×100 (A1)

Examples of the material contained in the moisture absorption particles may include one type selected from inorganic metal oxides such as barium oxide, magnesium oxide, calcium oxide, and strontium oxide, or a mixture or solid solution of two or more types thereof; an organic metal compound described in Japanese Patent Application Laid-Open No. 2005-298598 A; a substance capable of physically adsorbing water such as zeolite, silica gel, and activated alumina; hydrotalcite; and clay containing a metal oxide. Of these, one or more types of substances selected from the group consisting of zeolite, magnesium oxide, calcium oxide, and hydrotalcite are preferable as the material of the moisture absorption particles. Zeolite, magnesium oxide, calcium oxide, and hydrotalcite, which exhibit particularly high moisture absorption capacity, can easily achieve the high weight change ratio of 10% to 30%, for example, when they are allowed to stand at 20° C. and 90% RH for 24 hours. Further, zeolite releases water by drying and thus can be reused. Further, hydrotalcite also releases water by drying and thus can be reused. Hydrotalcite may be a natural hydrotalcite, a synthesized hydrotalcite (a hydrotalcite-like compound), or a mixture thereof. Hydrotalcite, which has less moisture absorption capacity than zeolite, can be used for drying under a low temperature drying condition, thereby facilitating a process. Further, magnesium oxide, which is converted to magnesium hydroxide by moisture absorption, has relatively moderate hygroscopicity, but exhibits favorable dispersibility. Further, calcium oxide is excellent in both hygroscopicity and dispersibility. As the material of the moisture absorption particles described above, one type thereof may be solely used, or two or more types thereof may be used in combination at any ratio.

The average particle diameter of the moisture absorption particles is preferably 5 nm or more, and particularly preferably 10 nm or more, and is preferably 2.5 μm or less, more preferably 200 nm or less, and particularly preferably 30 nm or less. When the average particle diameter of the moisture absorption particles is equal to or more than the aforementioned lower limit value, the particles can be dispersed with a small amount of the dispersant, thereby making it possible to improve hygroscopicity while reducing an adverse effect of the dispersant. When the average particle diameter of the moisture absorption particles is equal to or less than the aforementioned upper limit value, the thickness of the adhesive layer can be made uniform. Further, when the average particle diameter is equal to or less than 30 nm or less, the haze value can be reduced, thereby improving transparency of the adhesive layer.

In the present application, the average particle diameter of particles represents a number-average particle diameter unless otherwise specified. The number-average particle diameter of particles may be measured by a means for observing particles, such as an electron microscope.

The amount of the moisture absorption particles in the moisture absorption layer is usually 0.1 g/m² or more, preferably 0.5 g/m² or more, and more preferably 1 g/m² or more, and is usually 40 g/m² or less, preferably 25 g/m² or less, and more preferably 15 g/m² or less. The unit “g/m²” described above represents a weight of the moisture absorption particles per unit area of the moisture absorption layer. When the amount of the moisture absorption particles is equal to or more than the lower limit value of the aforementioned range, gas barrier properties of the thermoplastic elastomer layered body can be effectively improved. Further, when the amount of the moisture absorption particles is equal to or less than the higher limit value of the aforementioned range, transparency, flexibility, and processability of the thermoplastic elastomer layered body can be improved.

[3.2. Dispersant]

The dispersant is a material that disperses the moisture absorption particles in the moisture absorption layer material. Examples of the dispersant may include commercially available dispersants such as “ARON (registered trademark)” and “JURYMER (registered trademark)” series manufactured by Toagosei Co., Ltd., “AQUALIC (registered trademark)” series manufactured by Nippon Shokubai Co., Ltd., “FLOREN (registered trademark)” series manufactured by Kyoeisha Chemical Co., Ltd., “DISPARLON (registered trademark)” series manufactured by Kusumoto Chemicals, Ltd., “SOKALAN (registered trademark)” series manufactured by BASF SE, “DISPERBYK (registered trademark)” series manufactured by BYK-Chemie, “SOLSPERSE (registered trademark)” series manufactured by The Lubrizol Corp., and “AJISPER” series manufactured by Ajinomoto Fine-Techno Co., Inc. The dispersant may be constituted by a skeleton that is adsorbed to a particle and a skeleton that affects interaction or compatibility with a resin and a solvent. Examples of the skeleton that is adsorbed to a particle may include an amino group, a carboxyl group, a phosphate group, an amine salt, a carboxylate salt, a phosphate salt, an ether group, a hydroxyl group, an amido group, an aromatic vinyl group, and an alkyl group. In general, when a surface of the particle is acidic, a basic skeleton is selected as the skeleton that is adsorbed to the particle, while when the particle surface is basic, an acidic skeleton is selected. However, a nonionic skeleton may also be used. On the other hand, examples of the skeleton that affects interaction or compatibility with a resin and a solvent may include fatty acid, polyamino, polyether, polyester, polyurethane, and polyacrylate.

Further, silane coupling agents manufactured by Shin-Etsu Chemical Co., Ltd. and Dow Corning Toray Co., Ltd., or the like, may be used as the dispersant. As to the silane coupling agent, the portion that is adsorbed to a particle is referred to as a hydrolyzable group, and the portion that affects interaction or compatibility with a resin and a solvent is referred to as a reactive functional group. Examples of the hydrolyzable group may include —OCH₃, —OC₂H₅, and —OCOCH₃. On the other hand, examples of the reactive functional group may include an amino group, an epoxy group, a methacrylic group, and a vinyl group. As such a dispersant, one type thereof may be solely used, and two or more types thereof may also be used as a mixture.

The amount of the dispersant in the moisture absorption layer is preferably 1 part by weight or more, and more preferably 3 parts by weight or more, and is preferably 100 parts by weight or less, and more preferably 50 parts by weight or less, relative to 100 parts by weight of the moisture absorption particles. When the amount of the dispersant is equal to or more than the aforementioned lower limit, favorable dispersion of the moisture absorption particles can be achieved and thereby undesired phenomena such as an adverse effect of the secondary particle on a layer to be bonded can be prevented. Further, even when the amount of the dispersant is equal to or more than the aforementioned lower limit, an adverse effect by the dispersant on the layer to be bonded is suppressed since the thermoplastic elastomer layered body of the present invention has the specific layer configuration. On the other hand, when the amount of the dispersant is equal to or less than the aforementioned upper limit, it is possible to reduce an adverse effect of the dispersant on a layer to be bonded.

[3.3. Other Matters]

The moisture absorption layer material may contain a thermoplastic elastomer. The ratio of the thermoplastic elastomer in the moisture absorption layer material is not particularly limited, and may be, for example, the remainder of the moisture absorption particles and the dispersant. The thermoplastic elastomer may be the same material as either one or both of the first thermoplastic elastomer constituting the first resin layer and the second thermoplastic elastomer constituting the second resin layer described above, or may be different from these materials. Examples of the thermoplastic elastomer constituting the moisture absorption layer material may include the same examples as those of the thermoplastic elastomer constituting the first resin layer and the second resin layer described above. Favorable adhesion can be achieved by the moisture absorption layer material containing a thermoplastic elastomer. Further, the thermoplastic elastomer layered body of the present invention can be easily produced by an efficient production method such as coextrusion molding or the like by using, as the thermoplastic elastomer contained in the moisture absorption layer material, a thermoplastic elastomer having the same glass transition temperature as, or a glass transition temperature close to (for example, the difference in glass transition temperatures is within 30° C.) that of the thermoplastic elastomer constituting the first resin layer and the second resin layer.

[4. Layer Structure of Thermoplastic Elastomer Layered Body]

The thermoplastic elastomer layered body of the present invention may consist of only the first resin layer, the moisture absorption layer, and the second resin layer. Alternatively, it may include an optional layer in addition to these layers. From the viewpoint of usefully using the thermoplastic elastomer layered body as an adhesive layer, the thermoplastic elastomer layered body of the present invention may preferably consist of only the first resin layer, the moisture absorption layer, and the second resin layer. However, in order to facilitate handling of the thermoplastic elastomer layered body of the present invention prior to use as an adhesive layer, the thermoplastic elastomer layered body of the present invention may be stored and transported with a release film affixed to one or both surfaces thereof.

The thickness of the first resin layer and the second resin layer is preferably 1 μm or more, and more preferably 3 μm or more, and is preferably 20 μm or less, and more preferably 10 μm or less. When the thickness of the first resin layer and the second resin layer is equal to or more than the aforementioned lower limit value, it is possible to prevent a chemical reaction between a component of the moisture absorption layer and a layer to be bonded, and to prevent a physical adverse effect of the secondary particles of the moisture absorption particles. When the thickness of the first resin layer and the second resin layer is equal to or less than the aforementioned upper limit value, favorable adhesion can be achieved when the thermoplastic elastomer layered body of the present invention is used as an adhesive layer.

The thickness of the moisture absorption layer is preferably 1 μm or more, and more preferably 3 μm or more, and is preferably 30 μm or less, and more preferably 10 μm or less. A ratio of the thickness of the moisture absorption layer relative to the total thickness of the first resin layer and the second resin layer is preferably in a range of 0.5 to 5 when the total thickness of the first resin layer and the second resin layer is 1. When the thickness of the moisture absorption layer is equal to or more than the aforementioned lower limit value, effective moisture absorption can be easily achieved, and thereby, prevention of penetration of water can be easily achieved. When the thickness of the moisture absorption layer is equal to or less than the aforementioned upper limit value, favorable adhesion can be achieved when the thermoplastic elastomer layered body of the present invention is used as an adhesive layer.

When the thermoplastic elastomer layered body of the present invention is used as an adhesive layer in an organic EL device where light transmission is required, it is preferable that the thermoplastic elastomer layered body of the present invention has high transparency. For example, it is preferable that the total light transmittance of each of the first thermoplastic elastomer, the second thermoplastic elastomer, and the moisture absorption layer material measured as a test piece having a thickness of 1 mm is equal to or higher than a specific value. Specifically, the total light transmittance is usually 70% or more, preferably 80% or more, and more preferably 90% or more.

The glass transition temperature of the thermoplastic elastomer constituting the first resin layer, the second resin layer, and the moisture absorption layer is usually 40° C. or higher, preferably 50° C. or higher, and more preferably 70° C. or higher, and is usually 200° C. or lower, preferably 180° C. or lower, and more preferably 160° C. or lower. When a resin containing a block copolymer is used, for example, the resin may have a plurality of glass transition temperatures. In this case, it is preferable that the highest glass transition temperature of the resin falls within the aforementioned range. When the glass transition temperature falls within the aforementioned range, it is possible to balance the adhesiveness at the time of sealing the element and the maintenance of the performance after sealing.

[5. Method for Producing Thermoplastic Elastomer Layered Body]

The method for producing the thermoplastic elastomer layered body of the present invention is not particularly limited, and may be produced by any method. For example, the thermoplastic elastomer layered body may be produced by forming a layer of a resin constituting each layer and bonding these layers. Alternatively, the thermoplastic elastomer layered body including the first resin layer, the moisture absorption layer, and the second resin layer may be produced by a method such as coextrusion. In view of the production efficiency and the ability to efficiently form the thermoplastic elastomer layered body having layers with respective desired thicknesses, a method of production by coextrusion is preferable.

[6. Use Application of Thermoplastic Elastomer Layered Body]

The thermoplastic elastomer layered body of the present invention may be used as an adhesive layer. That is, the thermoplastic elastomer layered body of the present invention may be interposed between two layers that are required to be bonded and subjected to a treatment for expressing adhesiveness, thereby bonding the two layers to be bonded.

The treatment for expressing adhesiveness may specifically be a so-called hot melt treatment. That is, the treatment may be performed by heating the thermoplastic elastomer layered body of the present invention and, if necessary, applying a pressure to the two layers to be bonded. The treatment is performed at a treatment temperature which is usually (Tg+5)° C. or higher, preferably +(Tg+10)° C. or higher, and more preferably (Tg+20)° C. or higher. Herein, Tg represents a glass transition temperature of a resin constituting the thermoplastic elastomer layered body (the first thermoplastic elastomer, the second thermoplastic elastomer, and the moisture absorption layer material). When the resin constituting the thermoplastic elastomer layered body has a plurality of glass transition temperatures, the aforementioned Tg represents the highest glass transition temperature among them. This treatment can achieve favorable adhesion. The upper limit of the treatment temperature is usually (Tg+150)° C. or lower, preferably (Tg+120)° C. or lower, and more preferably (Tg+100)° C. or lower. By the treatment at a temperature equal to or lower than the upper limit, it is possible to effectively prevent the migration of the moisture absorption particles and the dispersant in the moisture absorption layer to the outermost surface of the thermoplastic elastomer layered body. As a result, it is possible to prevent the chemical reaction between the components of the moisture absorption layer and a layer to be bonded, and it is also possible to prevent the physical adverse effect of the secondary particles of the moisture absorption particles.

[7. Organic EL Device]

The thermoplastic elastomer layered body of the present invention may be usefully used particularly as an adhesive layer for bonding components of an organic EL device. The organic EL device including the thermoplastic elastomer layered body of the present invention will be described below as an organic EL device of the present invention.

The organic EL device of the present invention may include a substrate, and an electrode and a light-emitting layer disposed thereon. Specifically, the organic EL device of the present invention may include a substrate such as a glass plate, a first electrode disposed on a surface of the substrate, a light-emitting layer disposed on a surface of the first electrode, and a second electrode further disposed on a surface of the light-emitting layer. Configuring one of the first electrode and the second electrode as a transparent electrode and the other as a reflection electrode (or a combination of a transparent electrode and a reflection layer), light emission toward a transparent electrode side in response to electric current application to the electrodes can be achieved.

The organic EL device of the present invention may further include a gas barrier layer for preventing the penetration of water into the light-emitting layer. The organic EL device of the present invention, which includes the substrate, the gas barrier layer, and the electrodes and the light-emitting layer disposed therebetween, may have a configuration in which the electrodes and the light-emitting layer are sealed by the substrate and the gas barrier layer. The organic EL device of the present invention may include the thermoplastic elastomer layered body of the present invention as a layer interposed between the second electrode and the gas barrier layer. Adopting such a configuration allows the thermoplastic elastomer layered body of the present invention to function as an adhesive layer that bonds the second electrode with the gas barrier layer, thereby making it possible to effectively seal a layer such as the light-emitting layer and obtain the organic EL device having high durability. Specifically, it is possible to prevent problems such as generation of a large dark spot after using the organic EL device for a long period of time.

The gas barrier layer may be a layered body of a resin film and a gas barrier layer. For example, a gas barrier layered body that includes a resin film and an inorganic barrier layer formed on a surface of the resin film may be used as the gas barrier layer.

Preferable examples of the inorganic material that may be contained in the inorganic barrier layer may include metal; an oxide, a nitride, and a nitride oxide of silicon; an oxide, a nitride, and a nitride oxide of aluminum; DLC (diamond-like carbon); and a mixed material of two or more of them. Of these, in terms of transparency, a material containing silicon is preferable, and a silicon oxide and a silicon nitride oxide are particularly preferable. Further, DLC is particularly preferable in terms of affinity to the resin film.

Examples of the oxide of silicon may include SiOₓ.

In this formula, x is preferably in a range of 1.4<x<2.0 from the viewpoint of achieving both transparency and water vapor barrier properties of the inorganic barrier layer. Further, examples of the oxide of silicon may include SiOC.

Examples of the nitride of silicon may include SiN_{y}. In this formula, y is preferably in a range of 0.5<y<1.5 from the viewpoint of achieving both transparency and water vapor barrier properties of the inorganic barrier layer.

Examples of the nitride oxide of silicon may include SiOₚN_{q}. In a case where priority is placed on improving adhesion of the inorganic barrier layer, the inorganic barrier layer herein is preferably made as an oxygen-rich film by setting p and q in ranges of 1<p<2.0 and 0<q<1.0. In a case where priority is put on improving the water vapor barrier properties of the inorganic barrier layer, the inorganic barrier layer is preferably made as a nitrogen-rich film by setting p and q in ranges of 0<p<0.8 and 0.8<q<1.3.

Examples of the oxide, nitride, and nitride oxide of aluminum may include AlOₓ, AlN_{y}, and AlOₚN_{q}. Of these, SiOₚN_{q}, AlOₓ, and a mixture thereof are particularly preferable from the viewpoint of inorganic barrier properties.

The inorganic barrier layer may be formed on the surface of the resin film serving as a supporting body by, for example, a film formation method such as a vapor deposition method, a sputtering method, an ion plating method, an ion beam assisted vapor deposition method, an arc discharge plasma vapor deposition method, a thermal CVD method, and a plasma CVD method. Of these, a chemical vapor deposition method such as a thermal CVD method and a plasma CVD method is preferably used. In the chemical vapor deposition method, a flexible inorganic barrier layer can be formed by adjusting a gas component used in a film formation. Further, by obtaining the flexible inorganic barrier layer, the inorganic barrier layer is allowed to follow deformation of the resin film and a size change of the resin film under a high-temperature and high-humidity environment. Further, in the chemical vapor deposition method, the film formation can be performed at a high film formation rate under a low-vacuum environment, thus favorable gas barrier properties can be achieved.

In the gas barrier layered body, the inorganic barrier layer may be disposed on both surfaces of the resin film, however, the inorganic barrier layer is usually disposed on one surface of the resin film. In such a case, the inorganic barrier layer may be disposed facing toward the inside of the organic EL device or the outside of the organic EL device. The inorganic barrier layer is preferably disposed facing toward the inside of the organic EL device from the viewpoint of preventing a damage of the inorganic barrier layer after production of the device.

The organic EL device of the present invention may further include an optional layer such as a hole injection layer, a hole transport layer, an electron transport layer, and an electron injection layer between the first electrode and the second electrode. The organic EL device may include an optional configuration such as a wiring for applying electric current to the first electrode and the second electrode and a peripheral structure for sealing the light-emitting layer.

The organic EL device of the present invention may include the light-emitting layer in any mode. For example, the organic EL device of the present invention may be a display device that includes the light-emitting layer as a pixel for displaying an image. Alternatively, the organic EL device may be a light source device, such as a backlight device and an illumination device, which includes the light-emitting layer as a light-emitting body for supplying light.

### EXAMPLES

Hereinafter, the present invention will be specifically described by illustrating Examples. However, the present invention is not limited to the Examples described below. The present invention may be optionally modified for implementation without departing from the scope of claims of the present invention and the scope of their equivalents. In the following description, “%” and “part” representing quantity are on the basis of weight, unless otherwise specified. The operations described below were performed under the conditions of normal temperature and normal pressure, unless otherwise specified.

[Evaluation Methods]

[Method for Measuring Water Vapor Transmission Rate]

The gas barrier layered body was punched out into an appropriate size to obtain a sample. A pressure of water vapor corresponding to 90% Rh at 40° C. was formed on respective sides of the sample using a differential pressure-type measurement device (“DELTAPERM” manufactured by Technolox Ltd.) having a circular measurement region with a diameter of 8 cm to measure a water vapor transmission rate.

[Young's Modulus, Tensile Elongation, Storage Elastic Modulus, Loss Elastic Modulus, and Tanδ]

A Young's modulus and a tensile elongation at 23° C. were measured in accordance with JIS K7113. A storage elastic modulus, a loss elastic modulus, and tanδ in a temperature range of 40° C. or higher and 200° C. or lower were measured using a dynamic viscoelasticity measuring apparatus DMS6100 manufactured by Hitachi High-Tech Science Corp.

[Example 1]

(1-1. Hydrogenation Product of Block Copolymer) A hydrogenation product of a block copolymer having a triblock structure in which polymer blocks [A] were bonded to both ends of a polymer block [B] was produced using styrene as an aromatic vinyl compound and isoprene as a linear conjugated diene compound by the following procedures.

A reaction vessel equipped with a stirrer, in which an internal atmosphere had been sufficiently replaced with nitrogen, was charged with 256 parts of dehydrated cyclohexane, 25.0 parts of dehydrated styrene, and 0.615 part of n-dibutyl ether. While a mixture was stirred at 60° C., 1.35 parts of n-butyllithium (15% solution in cyclohexane) was added to the mixture to initiate polymerization. The mixture was further reacted at 60° C. for 60 minutes while being stirred. A polymerization conversion rate at this point was 99.5% (the polymerization conversion rate was measured by gas chromatography, and hereinafter the same applies).

Subsequently, 50.0 parts of dehydrated isoprene was added and the mixture was continuously stirred for 30 minutes at the same temperature. The polymerization conversion rate at this point was 99%.

Subsequently, 25.0 parts of dehydrated styrene was further added and the mixture was stirred for 60 minutes at the same temperature. The polymerization conversion rate at this point was almost 100%.

Then, 0.5 part of isopropyl alcohol was added to the reaction liquid to terminate the reaction and thereby obtain a solution (i) containing a block copolymer.

The block copolymer in the solution (i) thus obtained had a weight-average molecular weight (Mw) of 44,900 and a molecular weight distribution (Mw/Mn) of 1.03.

Subsequently, the solution (i) was transferred to a pressure-resistant reaction vessel equipped with a stirrer. Then, 4.0 parts of a silica-alumina supported nickel catalyst (E22U, a carrying amount of nickel of 60%; manufactured by JGC Chemical Industry Company) as a hydrogenation catalyst and 350 parts of dehydrated cyclohexane were added to the solution (1) and mixed. After replacing the atmosphere inside the reaction vessel with hydrogen gas, the block copolymer was hydrogenated by performing a hydrogenation reaction by further supplying hydrogen to the solution while being stirred at a temperature of 170° C. and a pressure of 4.5 MPa for 6 hours to obtain a solution (iii) containing a hydrogenation product (ii) of the block copolymer. The hydrogenation product (ii) in the solution (iii) had the weight-average molecular weight (Mw) of 45,100 and the molecular weight distribution (Mw/Mn) of 1.04.

After the completion of the hydrogenation reaction, the solution (iii) was filtered to remove the hydrogenation catalyst. Subsequently, 1.0 part of a xylene solution prepared by dissolving 0.1 part of a phosphorus-based antioxidant, 6-[3-(3-t-butyl-4-hydroxy-5-methylphenyl)propoxy]-2,4,8,10-tetrakis-t-butyldibenzo[d,f][1.3.2]dioxaphosphepin (“SUMILIZER (registered trademark) GP” manufactured by Sumitomo Chemical Industries Co., Ltd., hereinafter referred to as “antioxidant A”) was added to and dissolved in the filtered solution (iii) to obtain a solution (iv).

Subsequently, the solution (iv) was sequentially filtered through Zeta Plus (registered trademark) filter 30H (manufactured by Cuno, a pore diameter of 0.5 μm to 1 μm) and another filter made from a metal fiber (a pore diameter of 0.4 μm, manufactured by Nichidai Co., Ltd.) to remove minute solid components. The solvents cyclohexane and xylene, and other volatile components were removed from the filtered solution (iv) at a temperature of 260° C. and a pressure of 0.001 MPa or less using a cylindrical concentrator dryer (product name “Kontro” manufactured by Hitachi, Ltd.). Then, a solid content in a molten state was extruded in a stranded form from a die directly connected to the concentrator dryer described above. The extruded product was cooled and cut with a pelletizer to obtain 85 parts of pellets (v) containing the hydrogenated product of the block copolymer and the antioxidant A. The hydrogenated product of the block copolymer in the pellets (v) thus obtained had the weight-average molecular weight (Mw) of 45,000 and the molecular weight distribution (Mw/Mn) of 1.08. Further, the hydrogenation rate was 99.9%.

(1-2. Silane Modified Product of Block Copolymer)

To 100 parts of the pellets (v) obtained in (1-1), 2.0 parts of vinyl trimethoxysilane and 0.2 part of di-t-butyl peroxide were added to obtain a mixture. This mixture was kneaded at a barrel temperature of 210° C. and a retention time of 80 seconds to 90 seconds using a twin-screw extruder. The kneaded mixture was extruded and cut with a pelletizer to obtain pellets (vi) of a silane modified product of the block copolymer. A test piece was prepared from the pellet (vi) and a glass transition temperature Tg of the test piece was evaluated by a tanδ peak obtained by the dynamic viscoelasticity measuring apparatus, and it was 124° C. A peak value of tanδ of the pellet (vi) in a temperature range of 40° C. or higher and 200° C. or lower was 1.3. This pellet (vi) had a Young's modulus of 0.5 GPa and a tensile elongation of 550% at 23° C.

(1-3. Moisture Absorption Layer Material)

10 g of zeolite particles (an average particle diameter of primary particles in a dispersed state: 100 nm), 5 g of a dispersant (a special polyether, trade name “Floren NC-500” manufactured by Kyoeisha Chemical Co., Ltd.), and 185 g of toluene were mixed and stirred in a beads mill to prepare a 5% zeolite dispersion. 40 g of the pellets (vi) obtained in (1-2) and 160 g of toluene were mixed to dissolve the pellets and thereby prepare a 20% polymer solution. Equal amounts of the zeolite dispersion and the polymer solution thus prepared were weighed and then mixed to prepare a zeolite containing polymer solution. Further, the solvent of this solution was volatilized by warming to extract a solid portion. The solid portion was then kneaded and discharged at a temperature of 180° C. using a kneader and the product was cut with a pelletizer to obtain pellets (vii) of a moisture absorption layer material.

(1-4. Thermoplastic Elastomer Layered Body)

The pellets (vi) and the pellets (vii) were charged into an extrusion device for multilayer film equipped with three feeders to form a film by heating and extrusion. The extrusion was performed so as to obtain a two-type three-layer configuration, (upper layer of pellets (vi))/(middle layer of pellets (vii))/(lower layer of pellets (vi)). Further, the extrusion was performed so as to have a thickness of the upper layer of 5 μm, a thickness of the middle layer of 20 μm, and a thickness of the lower layer of 5 μm. In this manner, a thermoplastic elastomer layered body 1 having a two-type three-layer configuration with a total thickness of 30 μm was obtained. The thermoplastic elastomer layered body 1 thus obtained was stored under a nitrogen environment to prevent moisture absorption.

(1-5. Gas Barrier Layered Body)

SiOC having a film thickness of 500 nm was formed on one surface of a resin film (trade name “ZEONOR film ZF16” manufactured by ZEON Corp., a thickness of 100 μm) using a plasma CVD device to produce a gas barrier layered body 1 having a layer configuration of (resin film)/(SiOC layer). The water vapor transmission rate of the gas barrier layered body 1 was measured, and was found out to be about 3 to 4×10⁻³ g/m²/day.

(1-6. Organic EL Device)

A glass plate having a size of 5 cm×5 cm was prepared. The following layers were formed on the glass plate in the following order using the following materials.

Transparent electrode layer; tin-doped indium oxide (ITO)

Hole transport layer; 4,4′-bis[N-(naphthyl)-N-phenylamino]biphenyl (α-NPD)

Green light-emitting layer; pyrazoline derivative

Electron transport layer; phenanthroline derivative

Electron injection layer; lithium fluoride

Reflection electrode layer; Al

The formation of the transparent electrode layer was performed by a reactive sputtering method using an ITO target. The formation of the layers from the hole injection layer to the reflection electrode layer were performed by placing the glass substrate, on which the transparent electrode layer had been previously formed, in a vacuum vapor deposition device and sequentially vapor-depositing materials for the layers from the hole transport layer to the reflection electrode layer described above by a resistance heating method. The vapor deposition was performed at a system internal pressure of 5×10⁻³ Pa and an evaporation rate of 0.1 nm/s to 0.2 nm/s. The formation of the layers from the transparent electrode layer to the reflection electrode layer were performed using a vapor deposition mask that determined a 3-cm square region as a light-emitting region. The thickness of each layer was as follows: the glass plate was 0.7 mm; the transparent conductive layer was 130 nm; the hole transport layer was 35 nm; the green light-emitting layer was 40 nm; the electron transport layer was 30 nm; the electron injection layer was 10 nm; the reflection electrode layer was 70 nm. In this manner, an organic EL element having a 3-cm square light-emitting surface capable of displaying green light-emitting color was obtained.

On the reflection electrode layer of the organic EL element thus obtained, the thermoplastic elastomer layered body 1 obtained in (1-4) was disposed, and the gas barrier layered body 1 obtained in (1-5) was further disposed thereon. The gas barrier layered body 1 was disposed so that the surface on the SiOC layer side was directed to the organic EL element side. A product obtained by laminating the organic EL element, the thermoplastic elastomer layered body 1, and the gas barrier layered body 1 was passed through a roll laminator to bond these layers together. In the bonding, a roll temperature was set to 110° C. and an applied pressure was set to 0.3 MPa. In this manner, an organic EL device 1 having a layer configuration of (organic EL element)/(thermoplastic elastomer layered body 1)/(gas barrier layered body 1) was obtained. The organic EL device 1 thus obtained achieved favorable sealing by the thermoplastic elastomer layered body 1 and the gas barrier layered body 1.

(1-7. Evaluation)

The organic EL device 1 thus obtained was allowed to stand under an environment at 60° C. and 90% RH for 100 hours and then made light-emitting by applying electric current to observe a dark spot. The observation of the dark spot was performed by randomly selecting 10 of the dark spots and measuring a diameter of each dark spot. As a result, even the largest dark spot reached only about 10 μm in diameter.

[Example 2]

(2-1. Moisture Absorption Layer Material)

10 g of hydrotalcite particles (an average particle diameter of primary particles in a dispersed state: 100 nm), 2 g of a dispersant (a copolymer having an acidic group, trade name “DISPERBYK-102”, manufactured by BYK), and 188 g of toluene were mixed and stirred in a beads mill to prepare a 5% hydrotalcite dispersion. 40 g of the pellets (vi) obtained in (1-2) of Example 1 and 160 g of toluene were mixed to dissolve the pellets and thereby prepare a 20% polymer solution. Equal amounts of the hydrotalcite dispersion and the polymer solution thus prepared were weighed and then mixed to prepare a hydrotalcite containing polymer solution. Further, the solvent of this solution was volatilized by warming to extract a solid portion. The solid portion was then kneaded and extruded at a temperature of 180° C. using a kneader and an extruded product was cut with a pelletizer to obtain pellets (ix) of a moisture absorption layer material.

(2-2. Thermoplastic Elastomer Layered Body)

The pellets (vi) and the pellets (ix) were charged into an extrusion device for multilayer film equipped with three feeders to form a film by heating and extrusion. The extrusion was performed so as to obtain a two-type three-layer configuration, (upper layer of pellets (vi))/(middle layer of pellets (ix))/(lower layer of pellets (vi)). Further, the extrusion was performed so as to have a thickness of the upper layer of 5 a thickness of the middle layer of 20 and a thickness of the lower layer of 5 In this manner, a thermoplastic elastomer layered body 2 having a two-type three-layer configuration with a total thickness of 30 μm was obtained.

(2-3. Organic EL Device)

The same operations as those in (1-1) to (1-2) and (1-5) to (1-7) of Example 1 were performed except that the thermoplastic elastomer layered body 2 obtained in (2-2) was used instead of the thermoplastic elastomer layered body 1 obtained in (1-4) of Example 1. As a result, an organic EL device 2 having a layer configuration of (organic EL element)/(thermoplastic elastomer layered body 2)/(gas barrier layered body 1) was obtained. The organic EL device 2 thus obtained achieved favorable sealing by the thermoplastic elastomer layered body 2 and the gas barrier layered body 1.

(Evaluation)

The organic EL device 2 thus obtained was allowed to stand under the environment at 60° C. and 90% RH for 100 hours and then made light-emitting by applying electric current to observe a dark spot. The observation of the dark spot was performed by randomly selecting 10 of the dark spots and measuring a diameter of each dark spot. As a result, even the largest dark spot reached only about 10 in diameter.

[Comparative Example 1]

(C1-1. Film of Moisture Absorption Layer Material)

20 g of zeolite particles (an average particle diameter of primary particles in a dispersed state: 100 nm) were left in a vacuum drying oven at 180° C. for 30 minutes, and then was charged into a kneader together with 80 g of the pellets (vi) obtained in (1-2) of Example 1. They were kneaded in the kneader and discharged therefrom at a temperature of 180° C. and the product was cut with a pelletizer to obtain pellets (viii) of the moisture absorption layer material. The pellet (viii) was molded in a form of a film by an extruder to obtain a film C1 having a thickness of 30 μm. The obtained film C1 was stored under a nitrogen environment to prevent moisture absorption.

(C1-2. Organic EL Device)

The same operations as those in (1-5) and (1-6) of Example 1 were performed except that the film C1 obtained in (C1-1) was used instead of the thermoplastic elastomer layered body 1, whereby the organic EL device C1 was obtained. In the obtained organic EL device C1, favorable sealing with the film C1 and the gas barrier layered body 1 was achieved.

(C1-3. Evaluation)

The dark spot was observed using the organic EL device C1 thus obtained by the same operation as that of (1-7) of Example 1. As a result, the largest dark spot reached about 300 μm in diameter. In the observation of the organic EL device C1, it was observed that the large dark spot was generated from a portion where the zeolite particles were aggregated to form a nucleus.

[Comparative Example 2]

(C2-1. Solution of Moisture Absorption Layer Material)

10 g of the zeolite particles (an average particle diameter of primary particle in a dispersed state: 100 nm), 5 g of the dispersant (trade name “Floren NC-500” manufactured by Kyoeisha Chemical Co., Ltd.), and 185 g of toluene were mixed and stirred in a beads mill to prepare a 5% zeolite dispersion. 40 g of the pellets (vi) obtained in (1-2) of Example 1 and 160 g of toluene were mixed to dissolve the pellets and thereby prepare a 20% polymer solution. Equal amounts of the zeolite dispersion and the polymer solution thus prepared were weighed and then mixed to prepare a zeolite containing polymer solution.

(C2-2. Gas Barrier Layered Body with Moisture Absorption Layer)

The zeolite containing polymer solution obtained in (C2-1) was applied onto a surface of the gas barrier layered body 1 obtained in (1-5) of Example 1 on an SiOC layer side. The coating thickness of the solution was adjusted so that a thickness of the moisture absorption layer to be obtained became 30 μm. After the application, the zeolite containing polymer solution was dried on a hot plate at 110° C. and then further allowed to stand in a vacuum drying oven at 150° C. for 30 minutes to form a moisture absorption layer. In this manner, a gas barrier layered body C2 with the moisture absorption layer having a layer configuration of (resin film)/(SiOC layer)/(moisture absorption layer) was obtained. The gas barrier layered body C2 thus obtained was stored under a nitrogen environment to prevent moisture absorption.

The gas barrier layered body C2 was disposed on the reflection electrode layer of the organic EL element obtained in (1-6) of Example 1. The gas barrier layered body C2 was disposed so that the surface on the moisture absorption layer side was directed to the organic EL element side. This product obtained by stacking the organic EL element and the gas barrier layered body C2 was passed through the roll laminator for attempting to bond these layers together. In the bonding, a roll temperature was set to 110° C. and an applied pressure was set to 0.3 MPa. As a result, the gas barrier layered body C2 did not bond to the organic EL element and sealing could not achieved.

[Comparative Example 3]

(C3-1. Solution of Moisture Absorption Layer Material)

10 g of hydrotalcite (an average particle diameter of primary particles in a dispersed state: 100 nm), 2 g of the dispersant (a copolymer having an acidic group, trade name “DISPERBYK-102”, manufactured by BYK), and 188 g of toluene were mixed and stirred in a beads mill to prepare a 5% hydrotalcite dispersion. 40 g of the pellets (vi) obtained in (1-2) of Example 1 and 160 g of toluene were mixed to dissolve the pellets and thereby prepare a 20% polymer solution. Equal amounts of the hydrotalcite dispersion and the polymer solution thus prepared were weighed and then mixed to prepare a hydrotalcite containing polymer solution.

(Gas Barrier Layered Body with Moisture Absorption Layer)

The hydrotalcite containing polymer solution obtained in (C3-1) was applied onto a surface of the gas barrier layered body 1 obtained in (1-5) of Example 1 on the SiOC layer side. The coating thickness of the solution was adjusted so that the obtained moisture absorption layer had a thickness of 30 μm. After the application, drying was performed on a hot plate at 110° C. for 30 minutes to form a moisture absorption layer, whereby a gas barrier layered body C3 with the moisture absorption layer having a layer structure of (resin film)/(SiOC layer)/(moisture absorption layer) was obtained.

The gas barrier layered body C3 was disposed on the reflection electrode layer of the organic EL element obtained in (1-6) of Example 1. The gas barrier layered body C3 was disposed so that the surface on the moisture absorption layer side was directed to the organic EL element side. This product obtained by stacking the organic EL element and the gas barrier layered body C3 was passed through the roll laminator for attempting to bond these layers. In the bonding, the roll temperature was set at 110° C. and the applied pressure was set at 0.3 MPa. As a result, the gas barrier layered body C3 did not adhere to the organic EL element and sealing could not be achieved.

From the above results, it can be seen that the organic EL device of the present invention that includes the thermoplastic elastomer layered body of the present invention achieves the favorable sealing and reduces problems such as generation of the large dark spot.

### REFERENCE SIGN LIST

100: thermoplastic elastomer layered body
111: first resin layer
112: second resin layer
120: moisture absorption layer
121: resin
122: particles having hygroscopicity

1. A thermoplastic elastomer layered body comprising a first resin layer, a moisture absorption layer, and a second resin layer in this order, wherein
the first resin layer is formed of a first thermoplastic elastomer,
the moisture absorption layer contains particles that have hygroscopicity and are dispersed in the moisture absorption layer, and
the second resin layer is formed of a second thermoplastic elastomer.

2. The thermoplastic elastomer layered body according to claim 1, wherein the first thermoplastic elastomer and the second thermoplastic elastomer contain a hydrogenated styrene-isoprene copolymer or a silane modified product thereof as a main component.

3. The thermoplastic elastomer layered body according to claim 1, wherein the first thermoplastic elastomer and the second thermoplastic elastomer contain a silane modified product of a hydrogenated styrene-isoprene copolymer as a main component.

4. The thermoplastic elastomer layered body according to claim 1, wherein the moisture absorption layer contains a styrene-isoprene copolymer or a silane modified product thereof as a main component.

5. The thermoplastic elastomer layered body according to claim 1, wherein the moisture absorption layer contains a dispersant.

6. The thermoplastic elastomer layered body according to claim 1, wherein both the first resin layer and the second resin layer do not substantially contain a dispersant.

7. An organic electroluminescent device comprising the thermoplastic elastomer layered body according to claim 1.
